(19) United States
(12) Patent Application Publication
(10) Pub. No.: US 2024/0284758 A1
(43) Pub. Date: Aug. 22, 2024

(54) REFLECTIVE ELECTRODE AND DISPLAY DEVICE INCLUDING THE SAME

(71) Applicant: Samsung Display Co., Ltd., Yongin-Si (KR)

(72) Inventors: HYUNEOK SHIN, Yongin-si (KR); JUHYUN LEE, Yongin-si (KR); JOONYONG PARK, Yongin-si (KR); DOKEUN SONG, Yongin-si (KR); YUNG BIN CHUNG, Yongin-si (KR)

(21) Appl. No.: 18/508,235

(22) Filed: Nov. 14, 2023

(30) Foreign Application Priority Data
Feb. 17, 2023 (KR) 10-2023-0021118

(51) Int. Cl. H10K 59/80; H10K 59/38

(52) U.S. Cl. CPC H10K 59/80518; H10K 59/38; H10K 59/879; H10K 2102/102; H10K 2102/103; H10K 2102/351

(57) ABSTRACT

A reflective electrode includes a first conductive layer including aluminum (Al), a second conductive layer disposed on the first conductive layer and including titanium nitride (TiN), and a third conductive layer disposed on the second conductive layer and including silver (Ag).

### CROSS-REFERENCE TO RELATED APPLICATION(S)

This application claims priority under 35 USC § 119 to Korean Patent Application No. 10-2023-0021118 filed on Feb. 17, 2023, in the Korean Intellectual Property Office (KIPO), the entire disclosure of which is incorporated by reference herein.

### BACKGROUND

### 1. Field

Embodiments relate to a reflective electrode. More specifically, embodiments relate to a reflective electrode and a display device including the same.

### 2. Description of the Related Art

As information technology develops, the importance of display devices, which are communication media between users and information, is being highlighted. Accordingly, display devices such as liquid crystal display devices, organic light emitting display devices, plasma display devices, or the like are widely used in various fields.

Recently, a head mounted display (HMD) including such a display device has been developed. The head mounted display is a virtual reality (VR) or augmented reality (AR) glasses-type monitor device that is worn in a form of glasses, helmets, or the like and focuses on a distance close to the user's eyes. The head mounted display may provide an image displayed on the display device to the user's eyes through a lens.

### SUMMARY

Embodiments provide a reflective electrode with improved efficiency.

Embodiments provide a display device including the reflective electrode.

A reflective electrode according to an embodiment of the present disclosure includes a first conductive layer including aluminum (Al), a second conductive layer disposed on the first conductive layer and including titanium nitride (TiN), and a third conductive layer disposed on the second conductive layer and including silver (Ag).

In an embodiment, the reflective electrode may further include a fourth conductive layer disposed on the third conductive layer and including indium tin oxide (ITO).

In an embodiment, the first conductive layer may include an alloy of the aluminum.

In an embodiment, the third conductive layer may include an alloy of the silver and indium (In).

In an embodiment, the third conductive layer may include an alloy of the silver and copper (Cu).

In an embodiment, a thickness of the second conductive layer may be thinner than a thickness of each of the first conductive layer and the third conductive layer.

In an embodiment, a thickness of the first conductive layer may be in a range of about 400 Å to about 700 Å.

In an embodiment, a thickness of the second conductive layer may be in a range of about 10 Å to about 50 Å.

In an embodiment, a thickness of the third conductive layer may be in a range of about 200 Å to about 500 Å.

A display device according to an embodiment of the present disclosure includes a substrate, a reflective electrode disposed on the substrate and including a first conductive layer including aluminum, a second conductive layer disposed on the first conductive layer and including titanium nitride and a third conductive layer disposed on the second conductive layer and including silver, and a light emitting layer disposed on the reflective electrode.

In an embodiment, the reflective electrode may further include a fourth conductive layer disposed on the third conductive layer and including indium tin oxide.

In an embodiment, the first conductive layer may include an alloy of the aluminum.

In an embodiment, the third conductive layer may include at least one selected from an alloy of the silver and indium and an alloy of the silver and copper.

In an embodiment, a thickness of the second conductive layer may be thinner than a thickness of each of the first conductive layer and the third conductive layer.

In an embodiment, a thickness of the first conductive layer may be in a range of about 400 Å to about 700 Å.

In an embodiment, a thickness of the second conductive layer may be in a range of about 10 Å to about 50 Å.

In an embodiment, a thickness of the third conductive layer may be in a range of about 200 Å to about 500 Å.

In an embodiment, the substrate may include a base substrate including a silicon wafer which includes a plurality of grooves, and a plurality of pixel circuit parts respectively disposed in the plurality of grooves.

In an embodiment, the display device may further include a micro lens disposed on the light emitting layer and overlapping the reflective electrode in a plan view.

In an embodiment, the display device may further include a color filter disposed between the light emitting layer and the micro lens. The light emitting layer may include a light emitting material that emits white light.

In a display device according to embodiments of the present disclosure, the display device may include a reflective electrode having a multilayer structure including first, second, third and fourth conductive layers. Since the second conductive layer may include titanium nitride (TiN), diffusion of material between the first conductive layer and the third conductive layer may be prevented. In addition, since the first conductive layer may include aluminum (Al) and the third conductive layer may include silver (Ag), light reflectivity of the reflective electrode may be improved. In addition, since a thickness of the third conductive layer may be relatively thin, contamination of a substrate and a process chamber by by-products of dry etching may be prevented. That is, the third conductive layer may be formed through a dry etching process.

### BRIEF DESCRIPTION OF THE DRAWINGS

FIG. 1 is a plan view illustrating a display device according to an embodiment of the present disclosure.

FIG. 2 is an enlarged plan view of area A of FIG. 1.

FIG. 3 is a cross-sectional view taken along line I-I′ of FIG. 2.

FIG. 4 is an enlarged cross-sectional view of area B of FIG. 3.

FIGS. 5, 6, 7, 8, 9, 10, 11, 12 and 13 are cross-sectional views illustrating a method of manufacturing the display device of FIG. 3.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

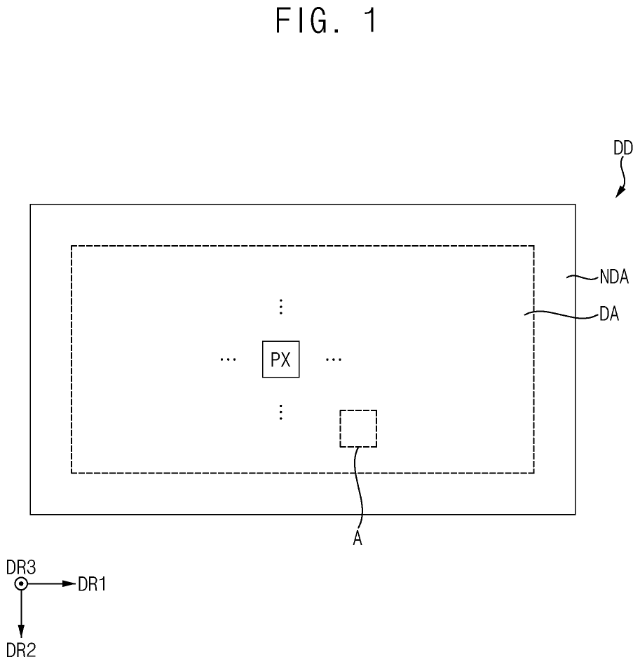

FIG. 1 is a plan view illustrating a display device according to an embodiment of the present disclosure.

Referring to FIG. 1, a display device DD according to an embodiment of the present disclosure may include a display area DA and a non-display area NDA.

The display area DA may be an area that displays an image. In the display area DA, a plurality of pixels PX may be repeatedly arranged along a first direction DR1 and a second direction DR2 intersecting the first direction DR1 in a plan view. For example, the second direction DR2 may be perpendicular to the first direction DR1. Each of the pixels PX may be a minimum light emitting unit that displays light.

Signal lines such as gate lines and data lines may be disposed in the display area DA. The signal lines may be connected to each of the pixels PX. Each of the pixels PX may receive a gate signal, a data signal, or the like from the signal lines. Accordingly, in the display area DA, an image may be displayed in a third direction DR3 intersecting each of the first direction DR1 and the second direction DR2. For example, the third direction DR3 may be perpendicular to each of the first direction DR1 and the second direction DR2.

The non-display area NDA may be an area that does not display an image. The non-display area NDA may be disposed around the display area DA. For example, the non-display area NDA may entirely surround the display area DA. Drivers for displaying an image of the display area DA may be disposed in the non-display area NDA.

In an embodiment, the display device DD may be a subminiature light emitting display device (or micro light emitting display device) including a subminiature light emitting diode (or micro light emitting diode) as a light emitting element. However, the present disclosure is not limited thereto. Alternatively, the display device DD may be an organic light emitting display device including an organic light emitting diode as a light emitting element.

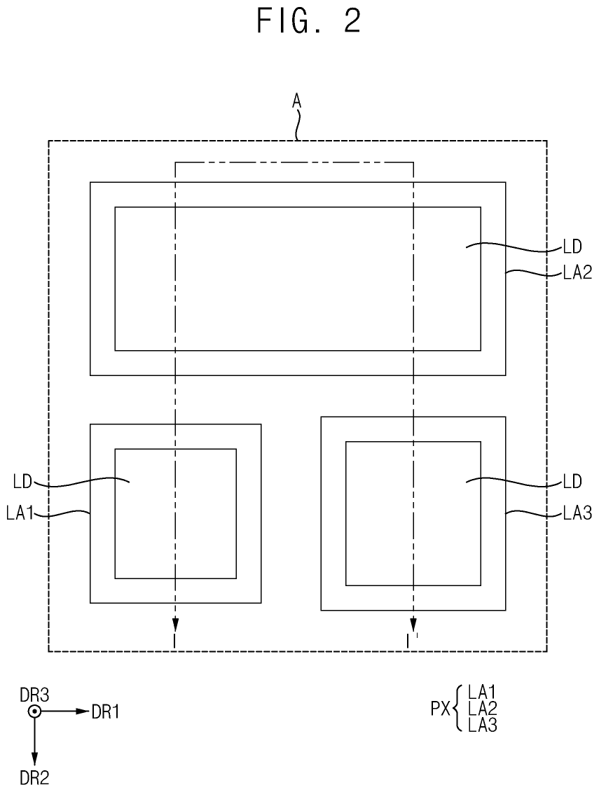

FIG. 2 is an enlarged plan view of area A of FIG. 1. For example, FIG. 2 may be an enlarged plan view of an example of the pixel PX included in the display device DD.

Referring to FIGS. 1 and 2, each of the pixels PX may include a first light emitting area LA1, a second light emitting area LA2 and a third light emitting area LA3 that emit light.

Each of the first, second and third light emitting areas LA1, LA2 and LA3 may include a light emitting element LD that emits a first light. For example, the first light may be white light, but the present disclosure is not limited thereto.

In addition, although FIG. 2 illustrates that the light emitting element LD has a rectangular planar shape, the present disclosure is not limited thereto. Alternatively, the light emitting element LD may have a polygonal, circular, elliptical or atypical planar shape other than the rectangular planar shape.

The first light emitting area LA1 may emit second light. In an embodiment, the first light emitting area LA1 may convert the first light emitted from the light emitting element LD into the second light and emit the second light. In another embodiment, the light emitting element LD may emit the second light, and the first light emitting area LA1 may emit the second light emitted from the light emitting element LD. For example, the second light may be light in a red wavelength band, but the present disclosure is not limited thereto.

The second light emitting area LA2 may emit third light. In an embodiment, the second light emitting area LA2 may convert the first light emitted from the light emitting element LD into the third light and emit the third light. In another embodiment, the light emitting element LD may emit the third light, and the second light emitting area LA2 may emit the third light emitted from the light emitting element LD. For example, the third light may be light in a blue wavelength band, but the present disclosure is not limited thereto.

The third light emitting area LA3 may emit fourth light. In an embodiment, the third light emitting area LA3 may convert the first light emitted from the light emitting element LD into the fourth light and emit the fourth light. In another embodiment, the light emitting element LD may emit the fourth light, and the third light emitting area LA3 may emit the fourth light emitted from the light emitting element LD. For example, the fourth light may be light in a green wavelength band, but the present disclosure is not limited thereto.

In an embodiment, the first light emitting area LA1, the second light emitting area LA2 and the third light emitting area LA3 may have different areas. For example, an area of the second light emitting area LA2 may be larger than an area of each of the first light emitting area LA1 and the third light emitting area LA3. In addition, the area of the third light emitting area LA3 may be larger than the area of the first light emitting area LA1. However, the present disclosure is not limited thereto. Alternatively, the first light emitting area LA1, the second light emitting area LA2 and the third light emitting area LA3 may have substantially the same area as each other.

In an embodiment, the first light emitting area LA1 and the third light emitting area LA3 may be disposed in the same row. In addition, the second light emitting area LA2 may be disposed on a different row from the first light emitting area LA1 and the third light emitting area LA3. For example, the third light emitting area LA3 may be disposed adjacent to the first light emitting area LA1 in the first direction DR1, and each of the first light emitting area LA1 and the third light emitting area LA3 may be disposed adjacent to the second light emitting area LA2 in the second direction DR2. However, the present disclosure is not limited thereto. Alternatively, the first light emitting area LA1, the second light emitting area LA2 and the third light emitting area LA3 may have various arrangements in the plan view.

Although FIG. 2 illustrates that each of the pixels PX includes three light emitting areas LA1, LA2 and LA3, the present disclosure is not limited thereto. Alternatively, each of the pixels PX may include four or more light emitting areas.

In addition, although FIG. 2 illustrates that each of the first light emitting area LA1, the second light emitting area LA2 and the third light emitting area LA3 has a rectangular planar shape, the present disclosure is not limited thereto. Alternatively, each of the first light emitting area LA1, the second light emitting area LA2 and the third light emitting area LA3 may have a polygonal, circular, elliptical or atypical planar shape other than the rectangular planar shape.

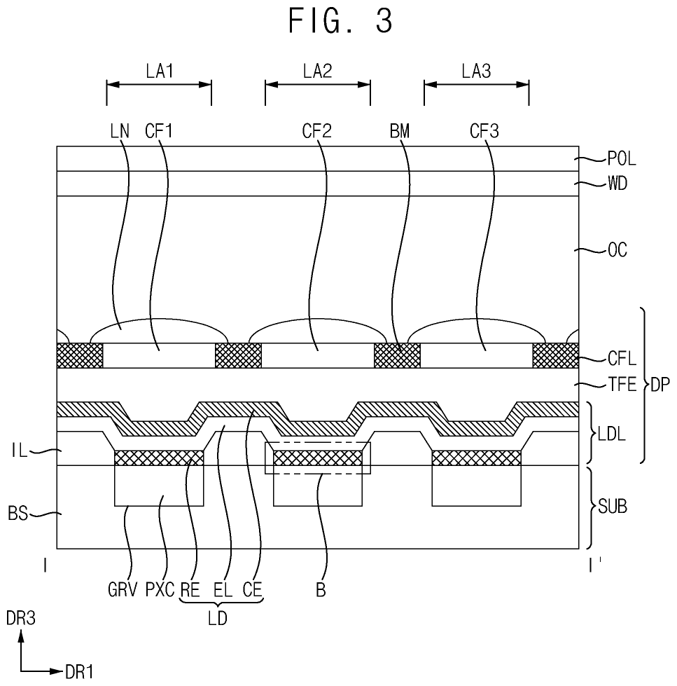

FIG. 3 is a cross-sectional view taken along line I-I′ of FIG. 2. FIG. 4 is an enlarged cross-sectional view of area B of FIG. 3. For example, FIG. 4 may be an enlarged cross-sectional view of a reflective electrode RE included in the display device DD.

Referring to FIGS. 1, 2, 3 and 4, the display device DD may include a substrate SUB, a display part DP, a planarization layer OC, a window WD and a polarization layer POL.

In an embodiment, the substrate SUB may be a semiconductor substrate. The substrate SUB may include a base substrate BS and a plurality of pixel circuit parts PXC. The base substrate BS may include a silicon wafer. In addition, the base substrate BS may include a plurality of grooves GRV. The pixel circuit parts PXC may be accommodated in the grooves GRV, respectively.

Each of the pixel circuit parts PXC may include at least one transistor. In addition, each of the pixel circuit parts PXC may further include at least one capacitor.

The display part DP may be disposed on the substrate SUB. The display part DP may include a light emitting element layer LDL, an encapsulation layer TFE, a color filter layer CFL and a plurality of micro lenses LN.

The light emitting element layer LDL may be disposed on the substrate SUB. The light emitting element layer LDL may include the light emitting elements LD and an insulating layer IL. Each of the light emitting elements LD may include the reflective electrode RE, a light emitting layer EL and a common electrode CE.

The reflective electrode RE may be disposed on the substrate SUB. The reflective electrode RE may overlap the pixel circuit part PXC, and may be connected to the pixel circuit part PXC. Accordingly, the reflective electrode RE may receive an anode voltage from the pixel circuit part PXC. For example, the reflective electrode RE may operate as an anode. In addition, the reflective electrode RE may reflect light emitted from the light emitting layer EL in the third direction DR3.

The reflective electrode RE may have a multilayer structure. In an embodiment, the reflective electrode RE may have a 4-layer structure. The reflective electrode RE may include a first conductive layer ML1 disposed on the substrate SUB, a second conductive layer ML2 disposed on the first conductive layer ML1, a third conductive layer ML3 disposed on the second conductive layer ML2 and a fourth conductive layer ML4 disposed on the third conductive layer ML3.

The first conductive layer ML1 may include a metal, an alloy, or the like. In an embodiment, the first conductive layer ML1 may include aluminum (Al), an alloy including aluminum, or the like. These may be used alone or in combination with each other. The first conductive layer ML1 may reflect light. Specifically, the first conductive layer ML1 may minimize light passing through the reflective electrode RE by reflecting light transmitted through the second, third and fourth conductive layers ML2, ML3 and ML4.

A thickness TH1 of the first conductive layer ML1 may be in a range of about 400 Å to about 700 Å. The thickness TH1 of the first conductive layer ML1 may be about 500 Å. When the thickness TH1 of the first conductive layer ML1 exceeds about 700 Å, it may be difficult to etch the first conductive layer ML1.

The second conductive layer ML2 may include a metal nitride having relatively high light transmittance. In an embodiment, the second conductive layer ML2 may include titanium nitride (TiN). In another embodiment, the second conductive layer ML2 may include aluminum nitride (AlN).

The second conductive layer ML2 may transmit light transmitted through the third and fourth conductive layers ML3 and ML4. In addition, the second conductive layer ML2 may prevent diffusion of materials included in the first conductive layer ML1 and a material included in the third conductive layer ML3. When the diffusion of the materials occurs between the first conductive layer ML1 and the third conductive layer ML3, light reflectance of the reflective electrode RE may decrease.

A thickness TH2 of the second conductive layer ML2 may be relatively thin. Specifically, the thickness TH2 of the second conductive layer ML2 may be smaller than the thickness TH1 of the first conductive layer ML1. In addition, the thickness TH2 of the second conductive layer ML2 may be smaller than a thickness TH3 of the third conductive layer ML3.

In an embodiment, the thickness TH2 of the second conductive layer ML2 may be in a range of about 10 Å to about 50 Å. The thickness TH2 of the second conductive layer ML2 may be about 50 Å. When the thickness TH2 of the second conductive layer ML2 exceeds about 50 Å, light transmittance of the second conductive layer ML2 may decrease and light absorbance of the second conductive layer ML2 may increase.

The third conductive layer ML3 may include a metal, an alloy, or the like having a relatively high light reflectivity. In an embodiment, the third conductive layer ML3 may include silver (Ag), an alloy including silver, or the like. For example, the third conductive layer ML3 may include an alloy of silver and indium (In). For another example, the third conductive layer ML3 may include an alloy of silver and copper (Cu). These may be used alone or in combination with each other. The third conductive layer ML3 may reflect light transmitted through the fourth conductive layer ML4.

The thickness TH3 of the third conductive layer ML3 may be in a range of about 200 Å to about 500 Å. The thickness TH3 of the third conductive layer ML3 may be in a range of about 200 Å to about 400 Å. Since the thickness TH3 of the third conductive layer ML3 may be relatively thin, contamination of the substrate SUB and a process chamber by etching by-products in a dry etching process of the third conductive layer ML3 may be prevented.

The fourth conductive layer ML4 may include transparent conductive oxide (TCO). In an embodiment, the fourth conductive layer ML4 may include indium tin oxide (ITO). A thickness TH4 of the fourth conductive layer ML4 may be in a range of about 50 Å to about 150 Å. The thickness TH4 of the third conductive layer ML3 may be about 70 Å. The first conductive layer ML1, the second conductive layer ML2, the third conductive layer ML3 and the fourth conductive layer ML1, ML2, ML3 and ML4 may constitute an anode.

The insulating layer IL may be disposed on the substrate SUB. The insulating layer IL may include an opening exposing at least a portion of the reflective electrode RE. In an embodiment, the insulating layer IL may include an organic insulating material. For example, the insulating layer IL may include a photoresist, a polyacrylic resin, a polyimide resin, an acrylic resin, or the like. These may be used alone or in combination with each other.

The light emitting layer EL may be disposed on the reflective electrode RE and the insulating layer IL. The light emitting layer EL may include an organic material that emits light of a predetermined color. For example, the light emitting layer EL may include an organic material that emits white light. The light emitting layer EL may further include at least one of a hole injection layer, a hole transport layer, an electron transport layer and an electron injection layer as an auxiliary layer that assists light emitting.

The light emitting layer EL may extend along the first, second and third light emitting areas LA1, LA2 and LA3. That is, the light emitting layer EL may continuously extend in the display area DA. However, the present disclosure is not limited thereto. Alternatively, a plurality of light emitting layers EL may be disposed in the first, second and third light emitting areas LA1, LA2 and LA3, respectively.

In an embodiment, the light emitting layer EL may include a plurality of organic light emitting layers. The organic light emitting layers may be sequentially stacked. Specifically, the light emitting layer EL may have a tandem structure including the organic light emitting layers overlapping in a thickness direction and charge generation layers disposed therebetween. For example, the organic light emitting layers may emit light of the same wavelength. Alternatively, the organic light emitting layers may emit light of different wavelengths.

The common electrode CE may be disposed on the light emitting layer EL. The common electrode CE may include a metal, an alloy, a metal nitride, a conductive metal oxide, a transparent conductive material, or the like. These may be used alone or in combination with each other. For example, the common electrode CE may be a cathode.

The encapsulation layer TFE may be disposed on the light emitting element layer LDL. The encapsulation layer TFE may include at least one inorganic encapsulation layer and at least one organic encapsulation layer. For example, the inorganic encapsulation layer and the organic encapsulation layer may be alternately stacked with each other. The encapsulation layer TFE may prevent foreign substances from penetrating into the light emitting element layer LDL.

The color filter layer CFL may be disposed on the encapsulation layer TFE. The color filter layer CFL may include a light blocking portion BM, a first color filter CF1, a second color filter CF2 and a third color filter CF3.

The light blocking portion BM may be disposed on the encapsulation layer TFE. The light blocking portion BM may define the first light emitting area LA1, the second light emitting area LA2 and the third light emitting area LA3. That is, the light blocking portion BM may define a plurality of openings partitioning the first, second and third light emitting areas LA1, LA2 and LA3. Accordingly, the light blocking portion BM may not overlap the first, second and third light emitting areas LA1, LA2 and LA3. The light blocking portion BM may include an organic material and/or an inorganic material including black pigment, black dye, or the like.

The first, second and third color filters CF1, CF2 and CF3 may be respectively disposed in the openings defined by the light blocking portion BM.

The first color filter CF1 may be disposed to overlap the first light emitting area LA1. The first color filter CF1 may transmit the second light, and may absorb or block the third light and the fourth light. For example, the first color filter CF1 may transmit light in a red wavelength band, and may absorb or block light in other wavelength bands, such as green, blue, or the like, but the present disclosure is not limited thereto.

The second color filter CF2 may be disposed to overlap the second light emitting area LA2. The second color filter CF2 may transmit the third light, and may absorb or block the second light and the fourth light. For example, the second color filter CF2 may transmit light in a blue wavelength band, and may absorb or block light in other wavelength bands, such as green, red, or the like, but the present disclosure is not limited thereto.

The third color filter CF3 may be disposed to overlap the third light emitting area LA3. The third color filter CF3 may transmit the fourth light, and may absorb or block the second light and the third light. For example, the third color filter CF3 may transmit light in a green wavelength band, and may absorb or block light in other wavelength bands, such as blue, red, or the like, but the present disclosure is not limited thereto.

The micro lenses LN may be disposed on the color filter layer CFL. The micro lenses LN may be respectively disposed on the first, second and third color filters CF1, CF2 and CF3. That is, the micro lenses LN may be disposed to overlap each of the first, second and third light emitting areas LA1, LA2 and LA3. Each of the micro lenses LN may have a convex lens shape. The micro lenses LN may improve light extraction efficiency.

The planarization layer OC may be disposed on the micro lenses LN. The planarization layer OC may have a substantially flat upper surface. For example, the planarization layer OC may include an organic material.

The window WD may be disposed on the planarization layer OC. The window WD may protect the display part DP and the substrate SUB. For example, the window WD may include glass.

The polarization layer POL may be disposed on the window WD. The polarization layer POL may reduce reflection of external light of the display device DD. As the reflection of external light may be reduced, visibility of the display device DD may be improved.

The display device DD according to an embodiment of the present disclosure may include the reflective electrode RE having a multilayer structure including the first, second, third and fourth conductive layers ML1, ML2, ML3 and ML4. Since the second conductive layer ML2 may include titanium nitride, material diffusion between the first conductive layer ML1 and the third conductive layer ML3 may be prevented. In addition, since the first conductive layer ML1 may include aluminum and the third conductive layer ML3 may include silver, light reflectance of the reflective electrode RE may be improved.

In addition, since the thickness TH3 of the third conductive layer ML3 may be relatively thin, contamination of the substrate SUB and the etching process chamber by etching by-products may be prevented. That is, the third conductive layer ML3 may be formed through a dry etching process.

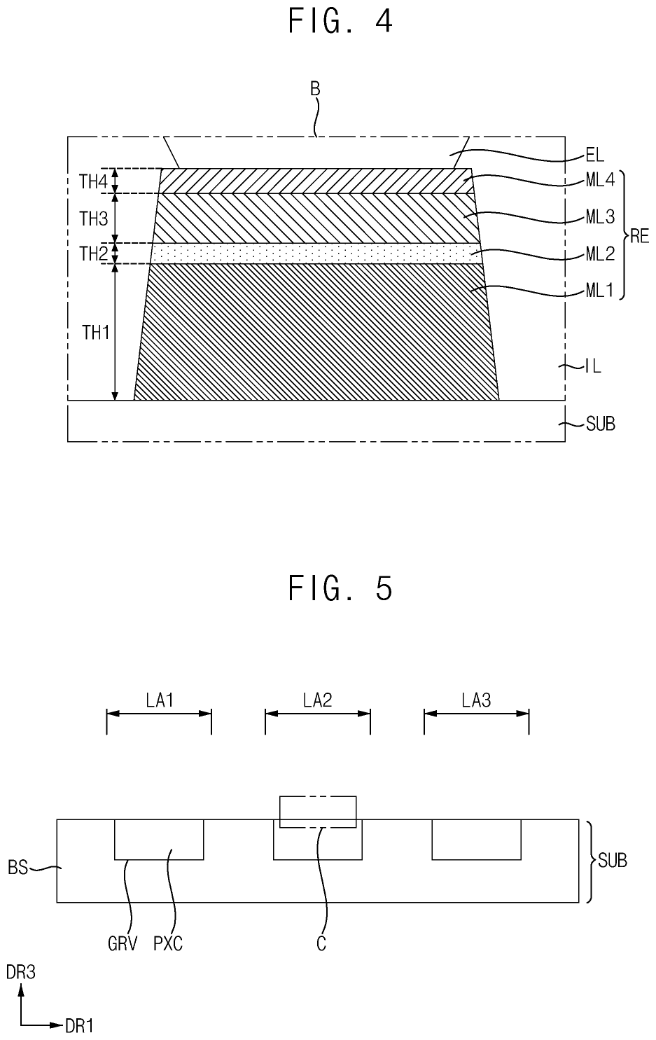

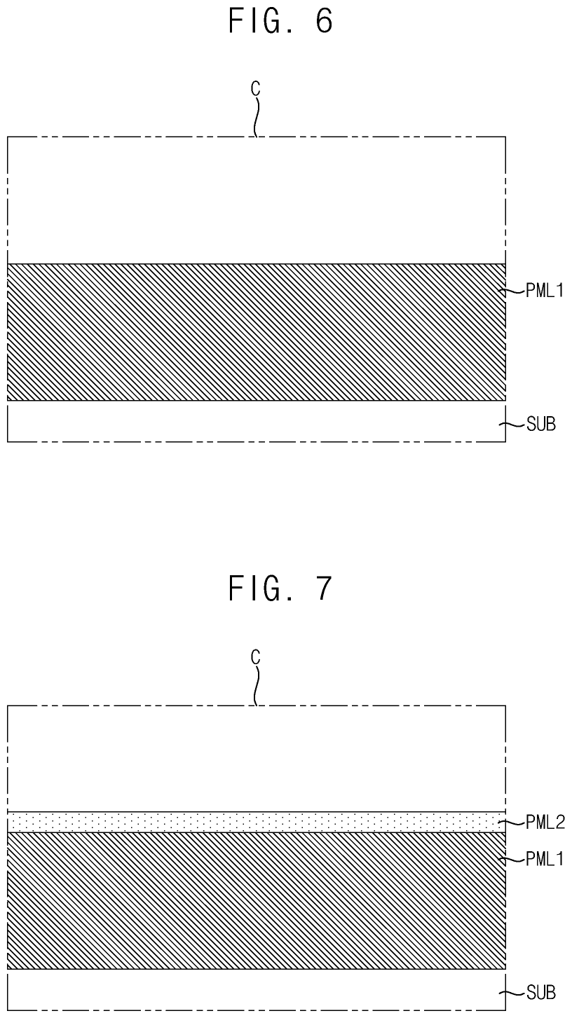

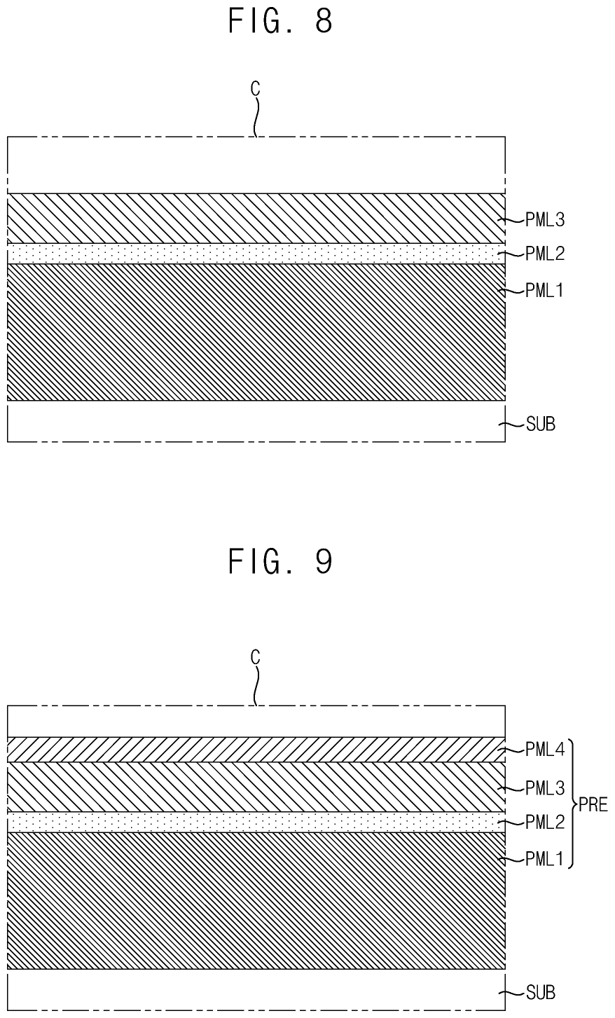

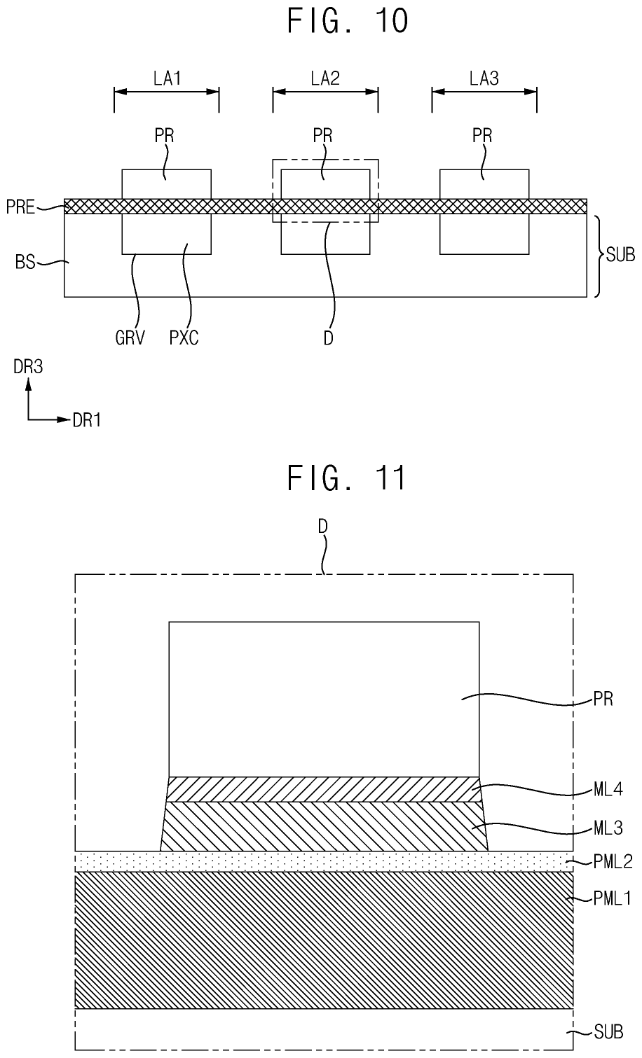

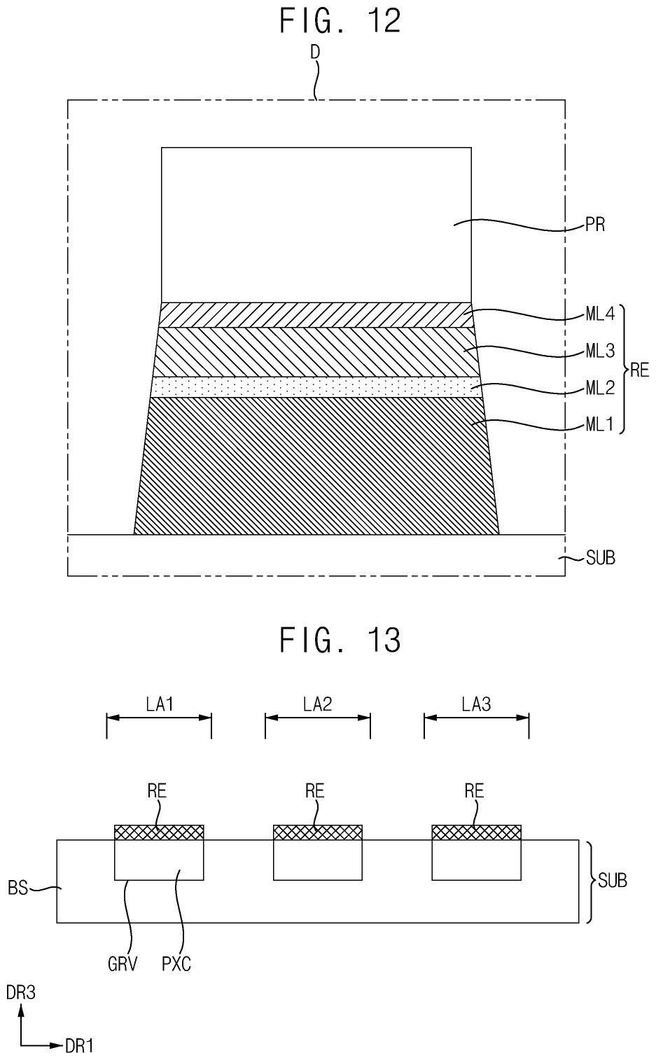

FIGS. 5 to 13 are cross-sectional views illustrating a method of manufacturing the display device of FIG. 3. For example, FIGS. 6, 7, 8 and 9 may be enlarged cross-sectional views of area C of FIG. 5, and FIGS. 11 and 12 may be enlarged cross-sectional views of area D of FIG. 10.

A method of manufacturing a display device described with reference to FIGS. 5 to 13 may be a method of manufacturing the display device DD described with reference to FIGS. 1, 2, 3 and 4. Therefore, redundant descriptions will be omitted or simplified.

Referring to FIGS. 5, 6, 7, 8 and 9, the substrate SUB may be provided. The substrate SUB may include the base substrate BS in which the grooves GRV are formed. The base substrate BS may be formed of a silicon wafer. The pixel circuit parts PXC may be respectively formed in the grooves GRV.

A preliminary first conductive layer PML1 may be formed on the substrate SUB in which the pixel circuit parts PXC are formed. In an embodiment, the preliminary first conductive layer PML1 may include aluminum, an alloy including aluminum, or the like.

A preliminary second conductive layer PML2 may be formed on the preliminary first conductive layer PML1. In an embodiment, the preliminary second conductive layer PML2 may include titanium nitride. In another embodiment, the preliminary second conductive layer PML2 may include aluminum nitride.

A preliminary third conductive layer PML3 may be formed on the preliminary second conductive layer PML2. In an embodiment, the preliminary third conductive layer PML3 may include silver, an alloy including silver, or the like. For example, the preliminary third conductive layer PML3 may include an alloy of silver and indium. For another example, the preliminary third conductive layer PML3 may include an alloy of silver and copper.

A preliminary fourth conductive layer PML4 may be formed on the preliminary third conductive layer PML3. In an embodiment, the preliminary fourth conductive layer PML4 may include a conductive oxide layer, for example, indium tin oxide.

The preliminary first conductive layer PML1, the preliminary second conductive layer PML2, the preliminary third conductive layer PML3 and the preliminary fourth conductive layer PML4 may form a preliminary reflective electrode PRE. In an embodiment, a thickness of the preliminary second conductive layer PML2 may be smaller than a thickness of each of the preliminary first conductive layer PML1 and the preliminary third conductive layer PML3.

Referring to FIGS. 9, 10, 11, 12 and 13, a photoresist pattern PR may be formed on the preliminary reflective electrode PRE. The photoresist pattern PR may overlap the first, second and third light emitting areas LA1, LA2 and LA3.

The preliminary fourth conductive layer PML4 and the preliminary third conductive layer PML3 may be patterned using the photoresist pattern PR as a mask.

In an embodiment, the preliminary fourth conductive layer PML4 and the preliminary third conductive layer PML3 may be sequentially dry etched to form the fourth conductive layer ML4 and the third conductive layer ML3. For example, the preliminary fourth conductive layer PML4 and the preliminary third conductive layer PML3 may be sequentially dry etched using argon (Ar) gas. Since the third conductive layer ML3 has a relatively thin thickness of about 200 Å to about 500 Å, contamination of the substrate SUB and the chamber that may occur due to dry etching of the preliminary third conductive layer PML3 may be prevented.

In another embodiment, the preliminary fourth conductive layer PML4 and the preliminary third conductive layer PML3 may be wet etched simultaneously to form the fourth conductive layer ML4 and the third conductive layer ML3. For example, the preliminary fourth conductive layer PML4 and the preliminary third conductive layer PML3 may be sequentially wet etched using an etchant having a slow etching rate for silver.

Then, the preliminary second conductive layer PML2 and the preliminary first conductive layer PML1 may be patterned using the photoresist pattern PR as a mask. In an embodiment, the preliminary second conductive layer PML2 and the preliminary first conductive layer PML1 may be sequentially dry etched to form the second conductive layer ML2 and the first conductive layer ML1. For example, the preliminary second conductive layer PML2 and the preliminary first conductive layer PML1 may be sequentially dry etched using chlorine (Cl) gas.

That is, the preliminary reflective electrode PRE may be patterned using the photoresist pattern PR as a mask to form the reflective electrode RE. The reflective electrode RE may be formed to overlap the first, second and third light emitting areas LA1, LA2 and LA3.

Referring back to FIG. 3, the insulating layer IL, the light emitting layer EL, the common electrode CE, the encapsulation layer TFE, the color filter layer CFL, the micro lenses LN, the planarization layer OC, the window WD and the polarization layer POL may be sequentially formed on the reflective electrode RE.

Accordingly, the display device DD shown in FIG. 3 may be manufactured.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A reflective electrode comprising:
a first conductive layer including aluminum (Al);
a second conductive layer disposed on the first conductive layer and including titanium nitride (TiN); and
a third conductive layer disposed on the second conductive layer and including silver (Ag).

2. The reflective electrode of claim 1, further comprising:
a fourth conductive layer disposed on the third conductive layer and including indium tin oxide (ITO).

3. The reflective electrode of claim 1, wherein the first conductive layer includes an alloy of the aluminum.

4. The reflective electrode of claim 1, wherein the third conductive layer includes an alloy of the silver and indium (In).

5. The reflective electrode of claim 1, wherein the third conductive layer includes an alloy of the silver and copper (Cu).

6. The reflective electrode of claim 1, wherein a thickness of the second conductive layer is thinner than a thickness of each of the first conductive layer and the third conductive layer.

7. The reflective electrode of claim 1, wherein a thickness of the first conductive layer is in a range of about 400 Å to about 700 Å.

8. The reflective electrode of claim 1, wherein a thickness of the second conductive layer is in a range of about 10 Å to about 50 Å.

9. The reflective electrode of claim 1, wherein a thickness of the third conductive layer is in a range of about 200 Å to about 500 Å.

10. A display device comprising:
a substrate;
a reflective electrode disposed on the substrate and including:
a first conductive layer including aluminum;
a second conductive layer disposed on the first conductive layer and including titanium nitride; and
a third conductive layer disposed on the second conductive layer and including silver; and
a light emitting layer disposed on the reflective electrode.

11. The display device of claim 10, wherein the reflective electrode further includes:
a fourth conductive layer disposed on the third conductive layer and including indium tin oxide.

12. The display device of claim 10, wherein the first conductive layer includes an alloy of the aluminum.

13. The display device of claim 10, wherein the third conductive layer includes at least one selected from an alloy of the silver and indium and an alloy of the silver and copper.

14. The display device of claim 10, wherein a thickness of the second conductive layer is thinner than a thickness of each of the first conductive layer and the third conductive layer.

15. The display device of claim 10, wherein a thickness of the first conductive layer is in a range of about 400 Å to about 700 Å.

16. The display device of claim 10, wherein a thickness of the second conductive layer is in a range of about 10 Å to about 50 Å.

17. The display device of claim 10, wherein a thickness of the third conductive layer is in a range of about 200 Å to about 500 Å.

18. The display device of claim 10, wherein the substrate includes:
a base substrate including a silicon wafer which includes a plurality of grooves; and
a plurality of pixel circuit parts respectively disposed in the plurality of grooves.

19. The display device of claim 10, further comprising:
a micro lens disposed on the light emitting layer and overlapping the reflective electrode in a plan view.

20. The display device of claim 19, further comprising:
a color filter disposed between the light emitting layer and the micro lens, wherein the light emitting layer includes a light emitting material that emits white light.
